(19) United States
(12) Patent Application Publication
(10) Pub. No.: US 2008/0165035 A1
(43) Pub. Date: Jul. 10, 2008

(54) Method and System for Customizing Keyboard Map Variants

(76) Inventors: Kenneth S. Bhella, Stony Brook, NY (US); Edwin Booth, Brooklyn, NY (US); Sajan Wilfred, Kerala (IN); Ian Peach, Reading (GB); Robert John Lieb, Central Islip, NY (US)

Correspondence Address: FAY KAPLUN & MARCIN, LLP, 150 BROADWAY, SUITE 702, NEW YORK, NY, 10038, US

(21) Appl. No.: 11/621,643

(22) Filed: Jan. 10, 2007

(51) Int. Cl. H03M 11/00

(52) U.S. Cl. 341/23

(57) ABSTRACT

A system may include (a) at least one key map variant which has a plurality of key values associated with corresponding keystrokes; (b) a character encoding chart which has a plurality of code values associated with corresponding characters of the character encoding chart; (c) an input data reader which receives input data. The input data contains at least one of the code values associated with at least one corresponding character of the character encoding chart. The system may also include (d) a translation table which translates the at least one of the code values of the input data into at least one of the key values associated with at least one corresponding keystroke.

### FIELD OF INVENTION

The present invention relates generally to the field of advance data capture on computing devices, and more particularly to systems and methods for generating a keyboard mapping variant and emulating a keyboard on a computing device according to the keyboard mapping variant.

### BACKGROUND

Current operating systems support hundreds of keyboard map layouts in order to allow for international localization of data input to a computer. With the global expansion of information technology into emerging markets, the ability to support multiple languages, as well as multiple variations of a particular language, on mobile computing devices has become an important factor of any organization or industry. To avoid the excessive time and labor expended on reconfiguring the settings of a keyboard, keyboard map variants may be stored on these computing devices. However, due to hardware and programming resource limitations such as the memory space of the devices, only a few variants in keyboard map layouts can be stored on these devices. Therefore, these computing devices are not able to keep up with constantly changing keyboard maps and it may be difficult for certain international customers to use these computing devices.

Specifically, the international customer is required to select one of the few commonly used keyboard map variants, despite the fact the selected mapping does not match the layout that appears on the native keyboard of the international customer. Alternatively, the international customer may use an ALT-keypad emulation feature, wherein ALT codes allow for additional characters to be inputted by entering a character code point simultaneously with an ALT-key. However, keypad emulation features, such as the one described above, are substantially slower than inputting data directly via a keyboard map variant. The lack of adequate keyboard mapping support forces the international customer to select from less than desirable solutions, and adapt to a non-native language. Furthermore, a host application may need to be modified in order to support non-optimal keyboard maps. The lack of keyboard mapping support may drastically impact the sales of computing devices in international regions of emerging markets.

### SUMMARY OF THE INVENTION

The present invention relates to a method and system for customizing keyboard map variants. The system may include (a) at least one key map variant which has a plurality of key values associated with corresponding keystrokes; (b) a character encoding chart which has a plurality of code values associated with corresponding characters of the character encoding chart; (c) an input data reader which receives input data. The input data contains at least one of the code values associated with at least one corresponding character of the character encoding chart. The system may also include (d) a translation table which translates the at least one of the code values of the input data into at least one of the key values associated with at least one corresponding keystroke.

### BRIEF DESCRIPTION OF THE DRAWINGS

FIG. 1a shows an exemplary character encoding chart of coded character set, according to the exemplary embodiments of the present invention.

FIG. 1b shows an exemplary keyboard map for the exemplary computing device according to the exemplary embodiments of the present invention.

FIG. 1c shows an exemplary translation table entry of the translation table and an exemplary compose table entry of a compose table according to the exemplary embodiments of the present invention.

FIG. 2 shows an exemplary system including components according to the present invention.

FIG. 3 shows an exemplary method for generating and using keyboard mapping variants according to the present invention.

FIG. 4a shows an exemplary display of a user interface for generating and using keyboard mapping variants according to the present invention.

FIG. 4b shows an exemplary display of a user interface for selecting a keyboard mapping variant from a library of keyboard maps according to the present invention.

FIG. 4c shows an exemplary display of a user interface for displaying a keyboard mapping variant in the English language according to the present invention.

FIG. 4d shows an exemplary display of a user interface for editing the keyboard mapping variant in the English language in order to create a custom-made keyboard mapping variant according to the present invention.

FIG. 4e shows an exemplary display of a user interface for creating a custom-made keyboard mapping variant from a blank keyboard map according to the present invention.

### DETAILED DESCRIPTION

The present invention may be further understood with reference to the following description of exemplary embodiments and the related appended drawings, wherein like elements are provided with the same reference numerals. The exemplary embodiments of the present invention are related to systems and methods for allowing a user of a computing device to generate a custom keyboard map variant. Specifically, the exemplary embodiments of the present invention are related to systems and methods for programming the computing device with the customer keyboard map variant, thereby allow the computing device to emulate the keyboard according to the user's desired keyboard mapping. The computing device may translate character encoding of input data, such as bar code data, into the appropriate input data that the user would have entered via manual entry on a native keyboard.

Character encoding includes a code that pairs a sequence of characters from a language set with another sequence, such as, for example, octets or electrical pulses, in order to facilitate the storage of text in computers and the transmission of text through telecommunication networks. A common example character encoding that is based on the Latin alphabet is the American Standard Code for Information Interchange (“ASCII”). ASCII encodes letters, numerals, and various other symbols into integers as well as into 7-bit binary versions of those integers. The 7-bit binary versions may be extended with an extra zero-bit to facilitate storage in 8-bit of an octet. Therefore, ASCII may be defined as a character representation computer code that specifies a correspondence between digital bit patterns and the symbols of a written language. Thus, ASCII allows digital devices to communicate with each other and to process, store, and communicate character-oriented information. The ISO 8859-1 standard is a superset of the ASCII developed by the International Organization of Standardization (“ISO”) as a standard character coding of the Latin alphabet. Similar to ASCII, each Latin character is encoded as a single eight-bit code value, wherein the code values can be used in almost any data interchange system to communicate in the languages that use Latin-based alphabets. Accordingly, the ISO 8859-1 standard has been established as the basis for numerous character maps, such as keyboard mapping and barcode encoding schemes. Each of these character maps assigns a unique ASCII/ISO 8859-1 value to every character within the respective character map. Those skilled in the art will understand that while one exemplary embodiment of the present invention may utilize the ISO 8859-1 standard for character encoding, various other embodiments within the scope of the present invention may include the use of alternate character encoding standards, such as, for example, other standards of the ISO 8859 series, ISO 10646 Universal Character Set, MS-Windows character sets, etc.

Each operating system may include a keyboard driver that associates specific ASCII/ISO 8859-1 values to a sequence of one or more keys on a keyboard. The positioning of the key may be optimized based on the native language of the locality of use for the operating system. A configuration utility of certain computing devices, such as, for example, an optical scanner, may be used to manually input and map the configuration of a keyboard into an appropriate character code. In addition, the configuration utility may allow for the selection of a previously created keyboard maps. The computing device may download the keyboard map selected by the user and emulate a keyboard variant according keyboard mapping.

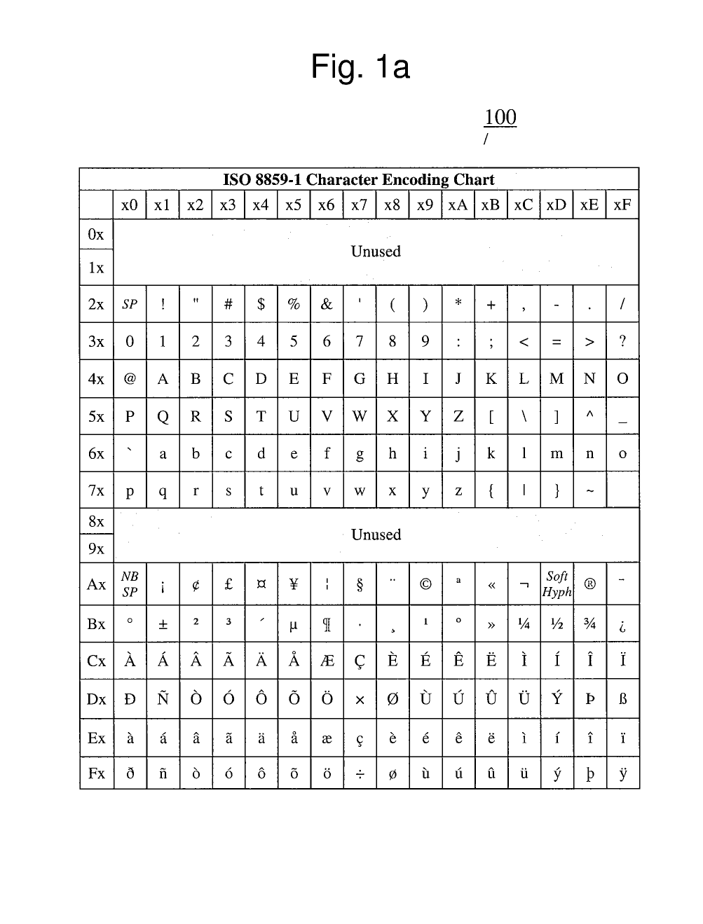

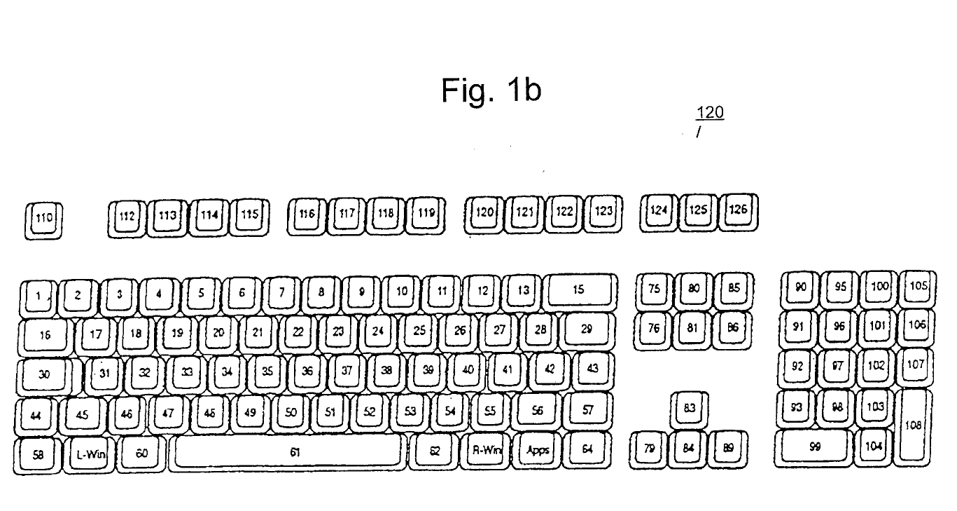

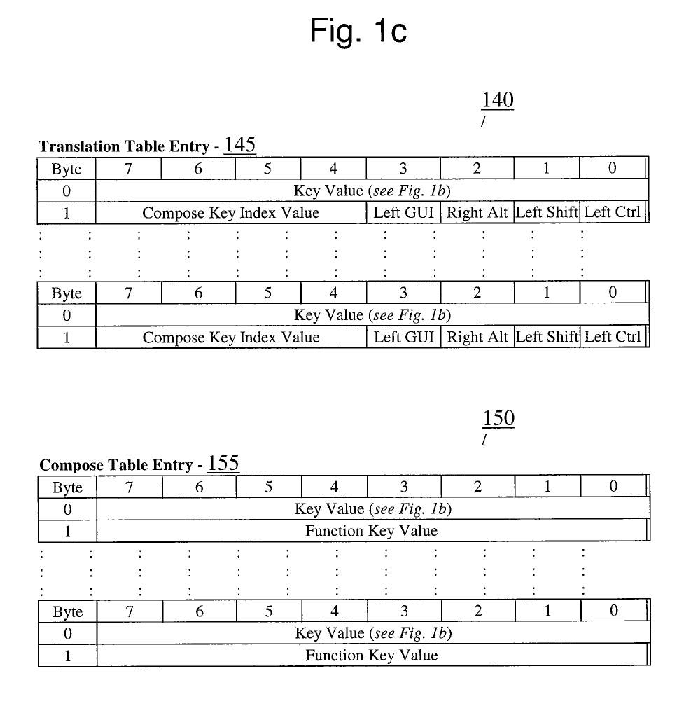

FIG. 1a shows an exemplary character encoding chart 100 of coded character set, according to the exemplary embodiments of the present invention. Specifically, character encoding chart 100 depicts each of the graphics for the coded character set of the ISO 8859-1 standard, wherein the row heading and column heading represent the hexadecimal digit combinations used to produce an eight-bit code value for each graphic. It is important to note that for the ISO 8859-1 standard, code values 00-1F, 7F and 80-9F are not assigned to any character graphics.

The character encoding chart 100 represents a closed group of graphics for the character set of the ISO 8859-1 standard, wherein no further characters may be added without creating a new standard. However, those skilled in the art will understand that any character set may be open, allowing for the addition of alternative characters, such as for example, variants of the Latin or Greek alphabet. Regardless of the characters included within the character set, each of the characters may have a unique code value assigned, or mapped, within a character encoding chart, such as chart 100, in order to allow the computing device to display an appropriate graphic representing each of the characters. In other words, the character encoding chart 100 specifies to the computing device exactly how each character is to be graphically represented through the use of the mapped code values. For example, as shown in FIG. 1, the graphic of a capital letter “A” may be mapped to the code value of “41” of the character set according to the ISO 8859-1 standard. However, the graphic of the capital letter “A” may be mapped to different code values within any number of alternate character sets. In addition, certain special characters of the ISO 8859-1 standard lack graphical representation. As seen in FIG. 1, these special characters include the space (“SP”), the non-breaking space (“NB SP”), and the soft hyphen (“Soft Hyph”). According to the exemplary character encoding chart 100, the non-graphical character SP is assigned the code value of “20,” the non-graphical character NB SP is assigned the code value of “A0,” and the non-graphical character Soft Hyph is assigned the code value of “AD.”

FIG. 1b shows an exemplary keyboard map 120 for the exemplary computing device according to the exemplary embodiments of the present invention, wherein each key on the keyboard is assigned a unique numerical key value. The computing device may receive a scancode from a keyboard driver indicating the key or keys that have been depressed by a user. The scancode may be defined as data representing the key value number, or sequence of key value numbers, assigned to the depressed key or keys. Those skilled in the art will understand that various scancodes may be utilized by different types of keyboards, such as USB keyboards, PS/2 keyboards, Bluetooth keyboards, etc. The scancode may be used by the keyboard driver to translate the numerical key value or values of the depressed key or keys into a graphical representation of a character, such as a character from the exemplary encoding chart 100 of FIG. 1a.

For example, the scancode on a standard U.S. keyboard map for the capital letter “A” would be one of the two Shift keys, either key value of “44” or “57,” in combination with the “A” key of key value “31.” According to this example, the keyboard driver would receive scancode of “44 and 31” or “57 and 31,” depending on which of the two Shift keys was depressed. The keyboard driver may then use a translation table to translate the key value into a code value, thereby determining which graphic of a character set corresponds to the key value combinations of either “44 and 31” or “57 and 31.” According to this example, the translation table may be associated with character encoding chart 100 having a character set of the ISO 8859-1 standard. Thus, both the key value combination of “44 and 31” and “57 and 31” may be translated to code value of “41.” Those skilled in the art will understand that, similar to the example for the capital letter “A,” several other characters of the encoding chart 100 that have a unique code value may be associated with multiple key values and/or key value combinations. For example, the character “*” may have a single code value of “2A” on the character encoding chart 100 of FIG. 1a. However, the key values for “*” according the keyboard map 120 of FIG. 1b may be both key value “100” and the key value combination of “44 and 9” or “57 and 9.”

The keyboard layout on the exemplary keyboard map 120 may vary for different languages in order to accommodate alternative and additional characters, and to improve efficiency for inputting data in the different language. Thus, the key value for one character may differ from language to language based on the placement of that character within the keyboard layout on the exemplary keyboard map 120. For example, while a French keyboard may utilize the exemplary keyboard map 120, the keyboard layout for the French keyboard may differ from the layout of the standard U.S. keyboard. Among other differences, the key assignments for the character “A” and “Q” are transposed on the French keyboard. As described above, the key value of the “A” key on the standard U.S. keyboard is “31.” Furthermore, the key value of the “Q” key on the standard U.S. keyboard is “17.” However, on the French keyboard, the key value of “A” is “17,” while the key value of “Q” is “31.” Thus, the same character may be assigned a different key value based on the character's location within the keyboard layout of a specific language. In order to allow for the proper association of the input received from a keyboard with the desired character, the exemplary embodiments of the present invention use various translation tables to decode the code values of the characters into key values on the keyboard map 120, and vice versa. The translation tables will be described in further detail below.

FIG. 1c shows an exemplary translation table entry 145 of the translation table 140 and an exemplary compose table entry 155 of a compose table 150 according to the exemplary embodiments of the present invention. Accordingly, each character on the character encoding chart 100 may comprise of a unique translation table entry 145, wherein the entry 145 may be an 8-bit octet including entry fields for a key value, a compose key index value, and additional function key identifiers. The function keys may include Shift keys, Alt-keys, Control keys, GUI-keys, Alternative Graphic keys (“Alt Gr-keys”) etc. The compose keys may include modifiers such as, for example, the single quote ('); the accent (`); the tilde (˜); the colon (:); the caret (̂); etc.

The entry field for the key value for the first row of the translation table entry 145 may contain the key value of the key according to assignments the keyboard map 120 of FIG. 1b. Within the second row of the translation table entry 140, the exemplary fields for the “Left Ctrl,” “Left Shift,” “Right Alt,” and “Left GUI” keys may be set when any of these function keys are to be depressed with sending the key value for a specific character. The compose key index field may be set to a non-zero number when a compose key index value of one of the compose keys is to be depressed prior to sending the key value of a corresponding character that is to be composed. This compose key index value of the compose table 150 may describe up to fifteen various compose keys that could be supported by the exemplary keyboard map 120.

Similar to the translation table entry 145, the compose table entry 155 may be an 8-bit octet including entry fields for a key value and a function key value. Accordingly, each of the compose keys may be assigned a compose key index value from 1 to 15. For example, when the character “ã” needs to be inputted on the standard U.S. keyboard, the compose key for the tilde modifier (˜) may need to be inputted prior to inputting the “a” key. Specifically, the modifier (˜) may be depressed along with the function “Left Ctrl” key prior to depressing the “a” key. According to this example, the compose key for the tilde modifier (˜) may be assigned the compose key index value, such as, for example, the compose key index value of “3.” Thus, when the compose key table 150 has a compose table entry 155 at index value “3” for the tilde modifier (˜), the exemplary compose table entry 155 would contain the key value of “1” (representing the assigned key value of the `/˜ key on the keyboard map 120) and the function key value of “58” (representing the assigned key value of the Left Ctrl key on the keyboard map 120). Therefore, in order to represent the “ã” character, the translation table entry 145 for “ã” would have the key number of “31” for the “a” and the compose key index value of “3” for the “˜”. Furthermore, the “Left Ctrl” bit would be set to indicate the use of this function key. In accordance with the above description for the character encoding chart 100, the translation table entry 145 for “ã” would be associated with the code value of “E3” on the encoding chart for the ISO 8859-1 standard.

It is important to note that while the French language may use the same character encoding chart 100, the variation in the mapping of the keyboard would require an entirely different translation table in order to associate the “ã” character with the code value of “E3” on the chart 100 for the ISO 8859-1 standard. Specifically, the translation table entry for the French language may have a key value of “17” due to the different keyboard layout. Furthermore, the compose key index value may be entirely unique to the French language. Thus, the use of the proper translation table 140 allows for the appropriate association between the input received from the keyboard and the graphic of the character to be displayed.

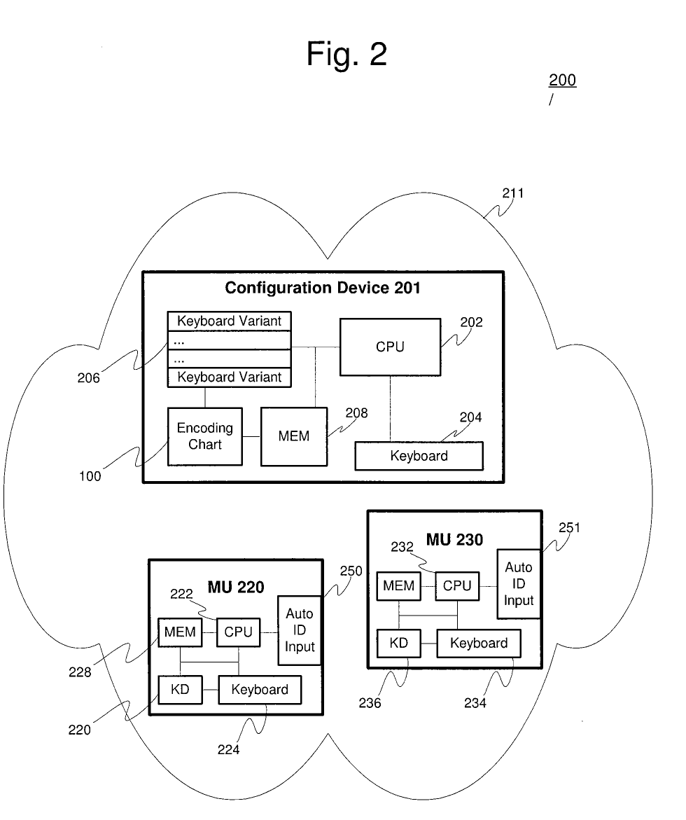

FIG. 2 shows an exemplary system 200 including components according to the present invention. The system 200 may include a computing device, such as configuration device 201, and at least one mobile computing device, such as mobile units (“MUs”) 220, 230. The device 201 may include a processor 202, a keyboard 204, a plurality of keyboard mapping variants 206, a memory 208, and a character encoding chart, such as, for example, character encoding chart 100. Each of the MUs 220, 230 may include a processor 222, 232, a keyboard 224, 234, a keyboard driver 226, 236, a memory 228, 238, as well as an automatic identification (“auto-id”) input device 250, 251 (e.g., a barcode scanner), respectively. Those skilled in the art will understand that various functionalities may be added to the MUs 220, 230 through software modules. The MUs 220, 230 may incorporate a variety of auto-id input methods for data capture such as, but not limited to, barcode scanning, imaging (e.g., photo capturing), radio frequency identification (“RFID”) tracking, optical character recognition (“OCR”), smart cards or integrated circuit cards, magnetic stripes, location awareness (e.g., real-time location systems (“RTLS”)), peer-to-peer communications (e.g., ad-hoc communications), biometric authentication, voice recognition, etc.

It is important to note that the functionalities and components of the configuration device 201 may be incorporated into a single device also having the functionalities and components of one of the MUs 220, 230. According to this embodiment, the single device may be capable of performing each of the inventive methods steps within the scope of the exemplary embodiments of the present invention. In other words, the single device may have the ability to create a keyboard mapping variant, emulate a keyboard according to the keyboard mapping variant, receive auto-id input data, and translate auto-id input data using the emulated keyboard.

The memories 208, 228, 238 may include either non-removable memory and/or removable memory. The removable memory may be any type of memory component that is integrated into the electronic architecture of the device 201 and MUs 220, 230, respectively. Furthermore, the non-removable memory may be temporary (e.g., random access memory, or RAM) or permanent (e.g., a hard-disk drive). The removable memory may be any type of detachable memory component that may connect to the devices 201 and MUs 220, 230 through an expansion interface, such as, for example, a universal serial bus (“USB”) mass storage device (e.g., a memory stick), a secure digital (“SD”) card, a mini SD card, a flash memory card, a flash drive, a smart media card, a Personal Computer Memory Card Industry Association card (“PCMCIA card”), a subscriber identity module (“SIM”) card, and any removable integrated circuit (“IC”) card that may be placed in electrical contact within the expansion interface of the device 201 and MUs 220, 230.

According to an exemplary embodiment of the present invention, the MUs 220, 230 may be in wireless communication with the configuration device 201. The exemplary system 200 may utilize a wireless local area network (“WLAN”) architecture 211 to provide continuous wireless coverage throughout an operating environment. Thus, the WLAN 211 may be described as a network infrastructure that allows for wireless devices, such as MUs 220, 230, to be in communication with the configuration device 201 via radio waves. Those skilled in the art will understand that the WLAN 211 is only exemplary and that the present invention may be applied to any type of wireless network topology. Alternatively or additionally, the configuration devices 201 may communicate with the MUs 220, 230 via a wired communication link (not shown). In a further embodiment, alternatively or additionally, the configuration device 201 may communicate with the MUs 220, 230 via a transferable removable memory component, such as, for example, via writing information onto a flash drive and connecting the flash drive to each one of the MUs 220, 230 in order to transfer the information.

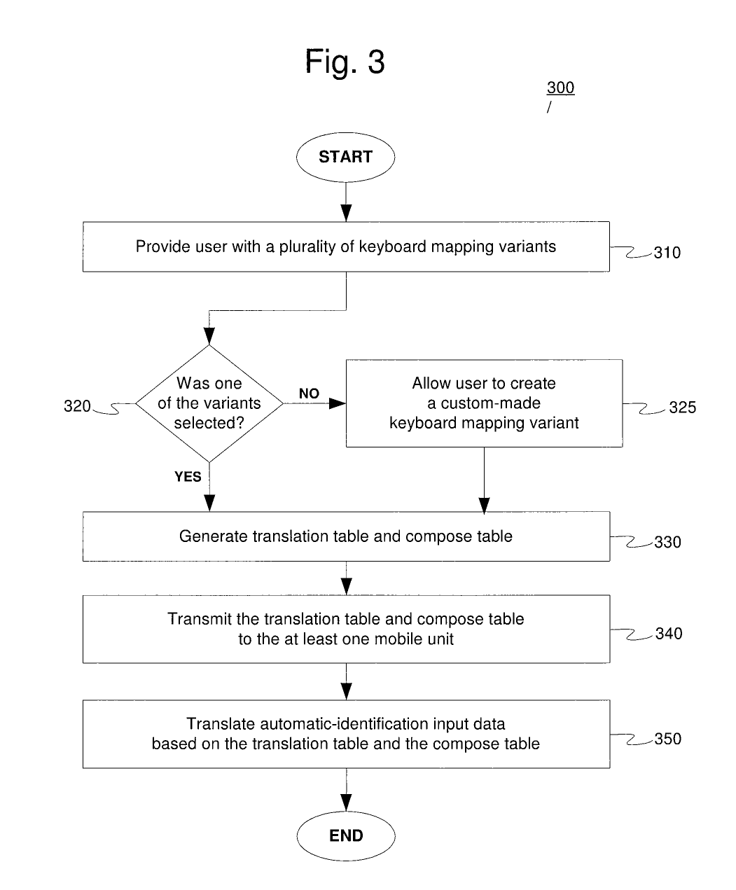

FIG. 3 represents an exemplary method 300 for generating and using keyboard mapping variants according to the present invention. The exemplary method 300 will be described with reference to chart, map, and table of FIGS. 1a-1c, as well as the exemplary system 200 of FIG. 2. According to exemplary embodiments of the present invention, the configuration device 201 may be used to manually map the configuration of keyboards 224, 234 of the MUs 220, 230, respectively. The configuration of the keyboards 224, 234 may be based off of the plurality of keyboard mapping variants 206, or alternatively, the configuration may be based on any custom-made keyboard map defined by a user via the keyboard 204 of the configuration device 201. The mapped keyboard configurations are downloaded by the MUs 220, 230, wherein the MUs 220, 230 are then able to emulate its keyboard 224, 234 according to the desired keyboard mapping. Once the desired keyboard mapping is emulated, the MUs 220, may then translate the auto-id input data to the appropriate scancodes that the user would have input had the user entered the data via the respective keyboards 224, 234.

In step 310, the configuration device 201 may provide a user with the plurality of keyboard mapping variants 206 that are supported by the configuration device 201. The user may be provided with the plurality of keyboard mapping variants 206 via a user interface, wherein the user interface may be display on the configuration device 201 and/or on one of the MUs 220, 230. As described above, the keyboard mapping variants 206 may reflect any variation between multiple languages or may simply represent multiple variations of a single language. The selection of keyboard mapping variants 206 may include pre-defined keyboard mapping variants, such as, for example, a standard U.S. keyboard layout (e.g., “QWERTY” layout), a French keyboard layout (e.g., “AZERTY” layout), a German keyboard layout (e.g., “QWERTZ” layout), etc. Thus, each character on the keyboard 224, 234 may be mapped various locations dependent on the selected keyboard mapping variant.

In step 320, the configuration device 201 may determine whether the user has selected one of the pre-defined keyboard mapping variants 206. If the configuration device 201 determines that the user has not selected a pre-defined variant, the method may process to step 325 wherein the configuration device 201 provides the use with the ability to define a custom-made keyboard mapping variant. The custom-made variant allows the user to map each character of the encoding chart 100 to any location within the keyboard map 120, thereby assigning unique key values to each character. Once the custom-made variant is created and selected by the user, the method 300 may proceed to step 330.

In step 330, the configuration device 201 may generate the translation table 140 and the compose table 150. As described above, the translation table 140 illustrates the association between the keystrokes (depressed character keys and function keys) with the code values of the character encoding charts 100. Specifically, the translation table 140 shows which key values need to be depressed on the keyboard map 120 in order to generate the associated graphic for the character.

In step 340, the configuration device 201 may transmit the translation table 140 and the compose table 150 to the at least one MU 220, 230 within the system 200. The MUs 220, 230 may receive the translation table 140 and the compose table 150 and store the information in respective memories 228, 238, of the MUs 220, 230. As described above, the transmission of the translation table 140 and the compose table 150 may be performed via wireless and/or wired communication, or may be transmitted via a transferable removable memory component. According to a further alternative embodiment, both the translation table 140 and the compose table 150 may be transferred to the MUs 220, 230 via an auto-id input data, such as, for example, via a barcode for storing the information. According to this further alternative embodiment, the translation table 140 and the compose table 150 may be programmed directly to the memories 228, 238 of the MUs 220, 230 using programming auto-id input data, such as, for example, programming barcodes having advanced data editing and formatting capabilities.

In step 350, the MUs 220, 230 may translate any received auto-id input data according to the keyboard mapping variant provided my the configuration device 201. Specifically, upon receiving the translation table 140 and the compose table 150 from the configuration device 201, the MUs 220, 230 may enable a keyboard emulation host, such as, for example, a USB keyboard emulation, a PS/2 keyboard emulation, a Bluetooth keyboard emulation, etc. The keyboard emulation host may allow for the emulation the keyboard mapping variant according the configuration selected by the user at the configuration device 201.

Therefore, according to the exemplary method 300 of the present invention, the information received via the auto-id input device 250, 251 may be translated into any number of keyboard mapping variants. Regardless of the order or the location of the keys as they appear on a keyboard, exemplary embodiments of the present invention allow the keyboard drivers 226, 236 of the MUs 220, 230 within the system 200 to associate the characters of any character encoding chart with keystroke, or combination of keystrokes, required to display that character.

As described above, the MUs 220, 230 may include auto-id input devices 250, 251, such as barcode scanners. The auto-id input device 250, 251 may be used to identify characters within the auto-id input data. For example, the auto-id input device 250, 251 may identify characters of the ISO 8559-1 character encoding chart 100. Through the use of the translation table 140 and the compose table 150, the keyboard drivers 226, 236 of the MUs 220, 230 may translate the code values of the character encoding chart 100 into a series of keystrokes. Upon translating the characters of the auto-id input data into keystrokes, the MU 220, 230 will be able to display the data to a user as if the user had input the data on a keyboard configured to the selected language variant.

According to an alternative embodiment of the present invention, the at least one exemplary MU 220 may not include a keyboard 224. The MU 220 according to this embodiment may simply collect information from the auto-id input device 250 and translate the characters of the collected information into corresponding keystrokes in association with a selected keyboard mapping variant. This collected information may or may not be displayed on the MU 220 to the user. Furthermore, the collected information may or may not be transferred to a host/centralized processing location.

According to a further alternative embodiment of the present invention, the at least one exemplary MU 220 may include a keyboard 224 that is not associated to the selected keyboard mapping variant. For example, the MU 220 may include keyboard 224 having a keyboard layout for a standard U.S. keyboard. However, the user may select the use of an unrelated keyboard mapping variant, such as, for example, a traditional Chinese keyboard layout. Accordingly, the MU 220 may receive and translate information into the proper keystrokes regardless of the layout of the keyboard hardware included on the MU 220.

According to a further alternative embodiment of the present invention, the configuration device 201 may maintain a library of mapping variants that includes the pre-defined keyboard mapping variants 206 as well as any of the custom-made keyboard mapping variants created by a user. Accordingly, the library mapping variants may be expanded, modified and/or updated on a continuous basis. Furthermore, the library of mapping variants may be transmitted to, or received from, other configuration devices, for example, via electronic communications such as e-mail. Therefore, the configuration device 201 may e-mail the library of keyboard mapping variants outside of the system 200 to at least a second configuration device, thereby allowing the second configuration device to transmit the received keyboard mapping variants to mobile computing devices within its respective system. Accordingly, the second configuration device may e-mail its respective library of keyboard mapping variants to the configuration device 201, thereby allowing both configuration devices to share the plurality of pre-defined and custom-made keyboard mapping variants maintained at each configuration device. Those skilled in the art will understand that e-mail is one of several communication methods in which the configuration device 201 may transmit or receive a library of keyboard mapping variants to and from another configuration device.

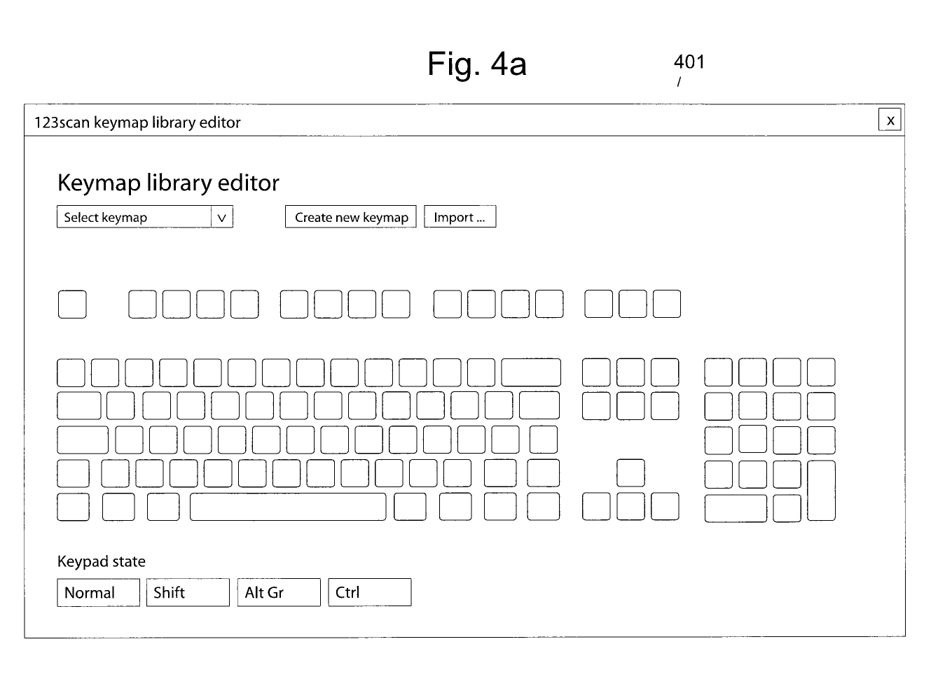

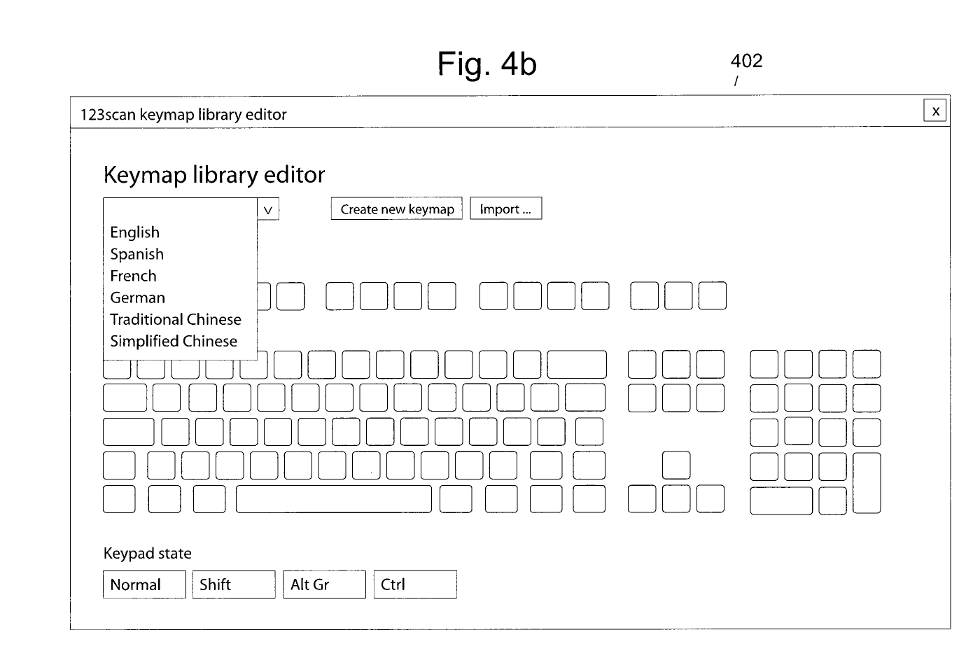

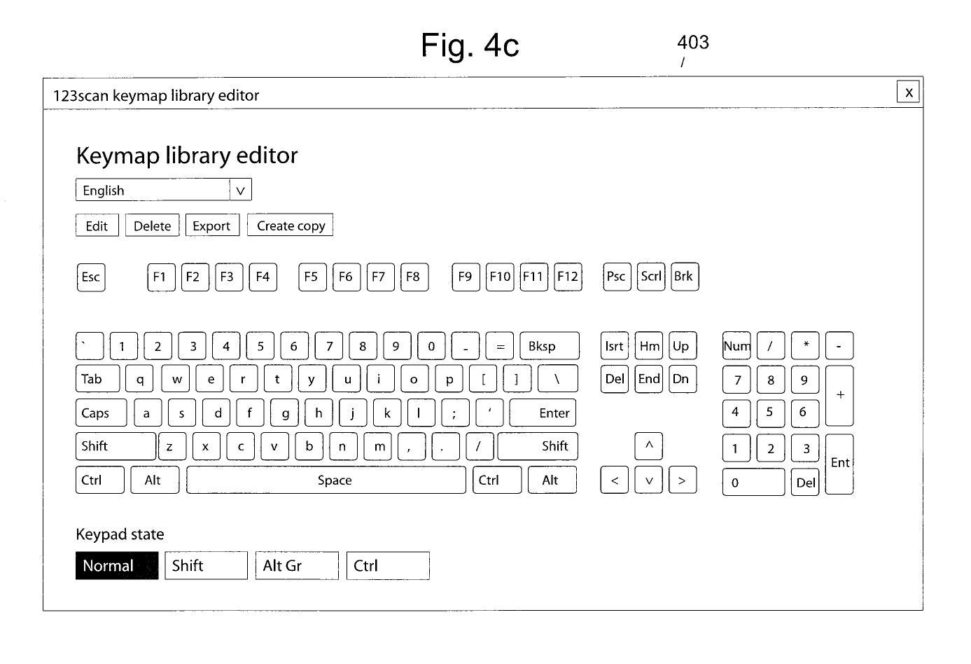

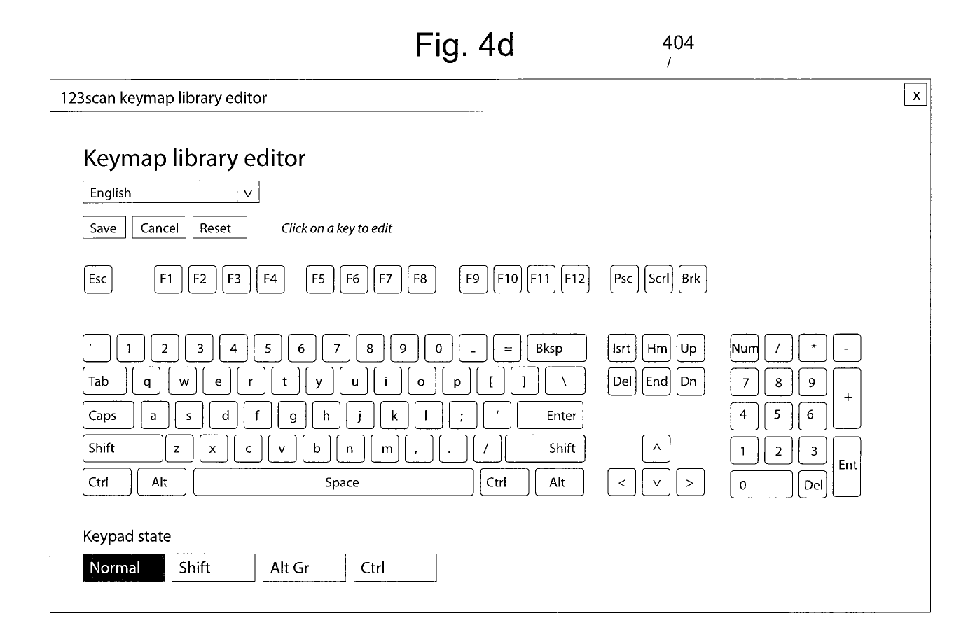

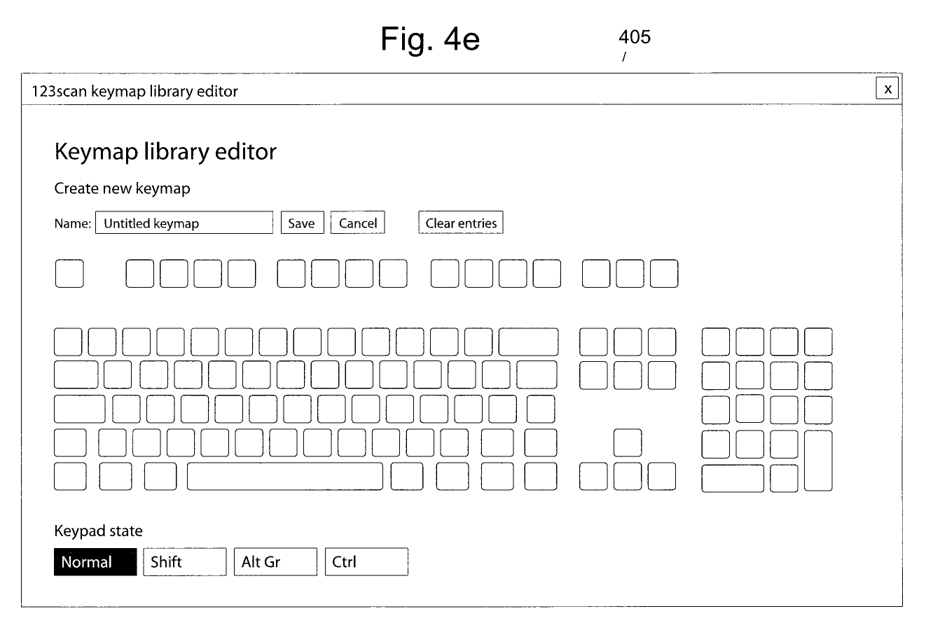

FIGS. 4a-4e represent exemplary displays 401-405 over a user interface for generating and using keyboard mapping variants according to the present invention. As described above, the user interface may be displayed on the configuration device 201 and/or on one of the MUs 220, 230. The user interface may allow the user to select a keyboard mapping variant from a library of keyboard mapping variants. Alternatively, the user interface may allow the user to create a custom-made keyboard mapping variant by editing an existing keyboard map or by assigning characters to a blank keyboard map. Those skilled in the art will understand that the format and design of the display 401-405 are for exemplary purposes, and the displays 401-405 may contain any combination of menus, selection buttons, drop-down lists, text boxes, check boxes, selection tabs, etc.

FIG. 4a shows an exemplary display 401 of a user interface for generating and using keyboard mapping variants according to the present invention. The exemplary display 401 may be the initial display shown to the user. The display 401 may include a drop-down list for selecting keyboard mapping variants, or “keymaps,” from a list of keymaps stored in a library. The display 401 also may include a plurality of “Keypad state” tabs. The “Keypad state” tabs may indicate which state (i.e., Normal, Shift, Alt Gr, Ctrl) of the keymap. For example, Normal may indicate the characters for each key when no function keys are depressed, while Shift may indicate the characters for each key when one of the shift keys is depressed.

The display 401 may further include selection buttons for “Create new keymap” and “Import.” As will be described in greater detail below, the “Create new keymap” button may allow the user to create a fully customized layout to the keyboard map. The “Import” button may allow the user to retrieve a new keymap from a remote location. The remote location may be the configuration device 201, a further configuration device, another MU, etc. For example, MU 220 may have a library of keymaps stored locally on the memory 228 of the MU 220. The MU 220 may import additional keymaps from the configuration device 201 via a wired or wireless transmission. Alternatively, the configuration device 201 may have its own library of keymaps stored locally on its memory 208. The configuration device 201 may communicate with a further configuration device, outside of the system 200, in order to import an additional keymap.

FIG. 4b shows an exemplary display 402 of a user interface for selecting a keyboard mapping variants from a library of keyboard maps according to the present invention. The exemplary display 402 may be shown to the user when the “Select keymap” drop-down list is selected from the exemplary initial display 401. Accordingly, the drop-down list may indicate the languages of keymaps that are available from the library of keymaps. Those skilled in the art will understand that any number of languages, as well as variants of a language, may be selectable from the “Select keymap” drop-down list. In addition, any previously stored or imported custom-made keymaps may be included in the drop-down list.

FIG. 4c shows an exemplary display 403 of a user interface for displaying a keyboard mapping variant in the English language according to the present invention. The exemplary display 403 may be shown to the user when “English” is selected from the exemplary display 402. By default, the display 403 may show the characters of the keymap in the Normal keypad state. Accordingly, the characters displayed on the keymap are the lower-case letters of the English language with numerals. Other keypad states (e.g., Shift, Alt Gr, Ctrl), or combinations of keypad states (e.g., Ctrl+Shift), may be selected by the user in order for the display 403 to show additional characters corresponding to that keypad state or combination of keypad states. It is important to note that once a keymap is selected, the exemplary display 403 may include additional selection buttons, such as, for example, “Edit,” “Delete,” “Export,” and “Create copy.” Each of these selection buttons may allow the user to customize the initial layout of the selected keymap. Furthermore, the “Export” button may allow the user to send the customized, or unaltered, keymap to a further configuration device and/or a further MU.

FIG. 4d shows an exemplary display 404 of a user interface for editing the keyboard mapping variant in the English language in order to create a custom-made keyboard mapping variant according to the present invention. The exemplary display 404 may be shown to the user when the “Edit” button is selected from the exemplary display 403. Once the “Edit” button is depressed, the exemplary display 404 may include additional selection buttons, such as, for example, “Save,” “Cancel,” and “Reset.” The “Save” button may allow the user to store the keymap locally, thereby adding the keymap to the library. The “Cancel” button may return the user to the exemplary display 403, thereby canceling the option to edit the keymap. The “Reset” button may revert the assignment of the characters to the original assignment of the selected keymap, such as, for example, the English keymap.

FIG. 4e shows an exemplary display 405 of a user interface for creating a custom-made keyboard mapping variant from a blank keyboard map according to the present invention. The exemplary display 405 may be shown to the user when the “Create new keymap” button is selected from the exemplary initial display 401. This option may allow the user to manually assign each character to a location on a blank keymap. Additionally, the user may assign additional characters for each of the keypad states by depressing the respective keypad state button, or any combination of keypad buttons. The “Clear entries” button may allow the user to delete all entries made to the customize keymap. Finally, the user may enter a name for the created keymap within the “Name” text box. The customized keymap may then be saved within the library of keymaps.

It will be apparent to those skilled in the art that various modifications may be made in the present invention, without departing from the spirit or the scope of the invention. Thus, it is intended that the present invention cover modifications and variations of this invention provided they come within the scope of the appended claimed and their equivalents.

What is claimed is:

1. A method, comprising:
receiving a selection of one of a plurality of key map variants, each variant including a plurality of values associated with corresponding keystrokes;
receiving input data; and
translating input data into the corresponding keystrokes of the selected variant.

2. The method according to claim 1, further comprising:
generating a translation table for each value of the selected variant.

3. The method according to claim 1, further comprising:
providing the plurality of key map variants to a user for a selection.

4. The method according to claim 2, further comprising:
transmitting the translation table to a mobile computing device; and
storing the translation table on a memory of the mobile computing device.

5. The method according to claim 4, wherein the transmitting of the translation table is one of a wired transmission and a wireless transmission.

6. The method according to claim 4, wherein the memory of the mobile computing device is one of a removable memory and a non-removable memory.

7. The method according to claim 4, wherein the translation table is encoded into an automatic identification (“auto-id”) data code and transmitted to the mobile computing device.

8. The method according to claim 7, wherein the auto-id data code is one of a barcode, a capturable image, a radio frequency identification (“RFID”) tracking tag, an optical character recognition (“OCR”) symbol, a smart card, an integrated circuit card, a magnetic stripe, biometric authentication data, and voice recognition data.

9. The method according to claim 4, wherein the mobile computing device is one of a barcode scanner, an image capturing device, a radio frequency identification tracker, an optical character recognition device, a smart card reader, an integrated circuit card reader, a magnetic stripe reader, a biometric authentication device, and a voice recognition device.

10. A system, comprising:
at least one key map variant including a plurality of key values associated with corresponding keystrokes;
a character encoding chart including a plurality of code values associated with corresponding characters of the character encoding chart;
an input data reader receiving input data, wherein the input data contains at least one of the code values associated with at least one corresponding character of the character encoding chart; and
a translation table translating the at least one of the code values of the input data into at least one of the key values associated with at least one corresponding keystroke.

11. The system according to claim 10, further comprising:
a user interface for receiving the selection of the at least one key map variant from a user, wherein the user interface includes a library of key map variants available for download and activation on a mobile computing device.

12. The system according to claim 11, wherein the user interface resides on one of a mobile computing device and a transmitting device.

13. The system according to claim 10, further comprising:
a transmitting device transmitting the translation table to a mobile computing device, wherein the translation table is stored on a memory of the mobile computing device.

14. The method according to claim 13, wherein the transmitting of the translation table is one of a wired transmission and a wireless transmission.

15. The method according to claim 13, wherein the memory of the mobile computing device is one of a removable memory and a non-removable memory.

16. The method according to claim 13, wherein the translation table is encoded into an automatic identification (“auto-id”) data code and transmitted to the mobile computing device via the transmitting device.

17. The method according to claim 16, wherein the auto-id data code is one of a barcode, a capturable image, a radio frequency identification (“RFID”) tracking tag, an optical character recognition (“OCR”) symbol, a smart card, an integrated circuit card, a magnetic stripe, biometric authentication data, and voice recognition data.

18. The method according to claim 13, wherein the mobile computing device is one of a barcode scanner, an image capturing device, a radio frequency identification tracker, an optical character recognition device, a smart card reader, an integrated circuit card reader, a magnetic stripe reader, a biometric authentication device, and a voice recognition device.

19. A system, comprising:
a selection receiving means receiving a selection of one of a plurality of key map variants, each variant including a plurality of values associated with corresponding keystrokes;
an input data receiving means receiving input data; and
a translating means translating input data into the corresponding keystrokes of the selected variant.

20. The system according to claim 19, further comprising:
a generating means generating a translation table for each value of the selected variant.

21. The system according to claim 20, further comprising:
a transmitting means transmitting the translation table to a mobile computing device; and
a storage means storing the translation table on a memory of the mobile computing device.

22. The system according to claim 21, wherein the transmitting of the translation table is one of a wired transmission and a wireless transmission.

23. The system according to claim 21, wherein the memory of the mobile computing device is one of a removable memory and a non-removable memory.

24. The system according to claim 21, wherein the translation table is encoded into an automatic identification (“auto-id”) data code and transmitted to the mobile computing device via the transmitting device.

25. The system according to claim 24, wherein the auto-id data code is one of a barcode, a capturable image, a radio frequency identification (“RFID”) tracking tag, an optical character recognition (“OCR”) symbol, a smart card, an integrated circuit card, a magnetic stripe, biometric authentication data, and voice recognition data.

26. The system according to claim 20, wherein the mobile computing device is one of a barcode scanner, an image capturing device, a radio frequency identification tracker, an optical character recognition device, a smart card reader, an integrated circuit card reader, a magnetic stripe reader, a biometric authentication device, and a voice recognition device.

27. A system, comprising a memory storing a set of instructions and a processor executing the instructions, the set of instructions being operable to:
receiving a selection of one of a plurality of key map variants, each variant including a plurality of values associated with corresponding keystrokes;
receiving input data; and
translating input data into the corresponding keystrokes of the selected variant.
